(19) United States
(12) Patent Application Publication
(10) Pub. No.: US 2026/0148787 A1
(43) Pub. Date: May 28, 2026

(54) OUTER PRODUCT ENGINE WITH CAPACITIVE DEVICE ARRAY

(71) Applicant: International Business Machines Corporation, Armonk, NY (US)

(72) Inventors: TAYFUN GOKMEN, Briarcliff Manor, NY (US); Takashi Ando, Eastchester, NY (US); Lior Horesh, North Salem, NY (US); Guy Moshe Cohen, Westchester, NY (US); Nanbo Gong, White Plains, NY (US); Vasileios Kalantzis, Nyack, NY (US)

(21) Appl. No.: 18/960,756

(22) Filed: Nov. 26, 2024

(51) Int. Cl. G11C 27/00; G06N 3/065; H10B 99/00

(52) U.S. Cl. CPC G11C 27/005; G06N 3/065; H10B 99/22

(57) ABSTRACT

A capacitor device associated with a capacitive processing unit provided at each node of a plurality of crossbar array nodes that perform neural network circuit operations, the capacitor device having a configurable capacitance representing a weight value. The capacitor device includes a stack containing first and second capacitor terminals and an insulating dielectric material layer therebetween. A floating gate layer is disposed within the insulating layer and configurable for storing charge carriers. A third capacitor terminal is a conductor separated from a first side edge of the floating gate layer by a first dielectric layer, and a fourth capacitor terminal is another conductor separated from the opposite side edge of the floating gate layer by a second dielectric layer. The weight value is programmable by modifying a capacitance of the capacitor device by injecting or removing charges at the floating gate layer using both the third and fourth capacitor terminals.

### BACKGROUND

The present application generally relates to neural networks, such as deep neural network (DNN) circuits and systems, and particularly, a novel capacitive processing unit that can accelerate DNN training with an analog weight update.

Deep neural network (DNN) techniques have demonstrated great success in machine learning applications in various technical fields including automatic recognition systems, such as character recognition systems, pattern recognition, speech recognition and voice recognition systems, etc., activation control systems for robots and neuro computer systems incorporating artificial intelligence. Most DNN are realized through software, which is extensively time and power consuming.

Current-based nonvolatile memory (NVM) devices represent states with different resistance values and are attractive for neural network acceleration. Current-based memory devices with resistance-based processing units (RPU) implementing analog weight update in a crossbar configuration can implement vector-matrix multiplication in neural network computations. By mapping an input vector to input voltages and weight matrix to a resistive crossbar array, vector matrix multiplication can be calculated in a single step by sampling the current flowing in each array column. This approach can be several orders of magnitude more efficient than CMOS ASIC approaches in terms of both speed and power.

Recently, compact memory unit cell structures with a capacitor as the analog information storage element have been used to store analog information in neutral network. A hardware approach for DNN including use of capacitive processing units (CPU) greatly improve processing speed. For example, capacitive device arrays can perform vector-matrix multiplication at a thousand times greater speed than software methods.

### SUMMARY

A novel capacitor device for a capacitive processing unit (CPU) of a hardware-based neural network circuit including a crossbar array configuration of a plurality of memory cells and a method of operating the CPU.

Each of the plurality of memory cells in the crossbar array includes a CPU including a capacitor device having two additional terminals configured to perform an analog weight update operation permitting a more efficient outer product computation (e.g., increased speed).

The two additional terminals of the capacitor device of a CPU facilitate an analog weight update operation for an outer-product computation that is part of a deep neural network training algorithm. Each capacitor of the CPU receiving at the two additional terminals either voltage or current pulses along a respective conductor connecting each respective additional terminal that shifts the capacitance of the capacitor device which significantly widens the dynamic range of capacitance tuning and improves the signal to noise ratio of the CPU-based weight storage array.

The two additional terminals of the capacitor device of a CPU receive either voltage or current pulses configured to increment or decrement the capacitance of the capacitor device proportional to the number of pulse coincidences determined for the outer product weight update operation.

In one aspect, there is provided a capacitor device. The capacitor device comprises: a first conductive layer providing a first capacitor terminal and a second conductive layer providing a second capacitor terminal and an insulating dielectric material layer therebetween, the first conductive layer, second conductive layer and insulating dielectric material layer forming a stack; a floating gate semiconductor material layer disposed within the insulating material layer and configured for storing charge carriers; a first dielectric material layer formed along a sidewall of the stack and contacting a side edge of the floating gate semiconductor material layer; a second dielectric material layer formed along an opposing sidewall of the stack and contacting an opposite side edge of the floating gate semiconductor material layer; a first conductive electrode providing a third capacitor terminal separated from the side edge of the floating gate semiconductor material layer by the first dielectric material layer, and a second conductive electrode providing a fourth capacitor terminal separated from the opposite side edge of the floating gate semiconductor material layer by the second dielectric material layer; the capacitor device associated with a weight update circuit at a crossbar array node of a neural network circuit, a capacitance of the capacitor device taken across the first and second capacitor terminals representing a weight value used in a neural network circuit operation.

In a further aspect, there is provided a neural network circuit. The neural network circuit comprises: a crossbar array comprising a plurality of nodes; each node comprising a capacitive processing unit (CPU) including a capacitor device configured to store a charge representing a weight value associated with a neural network circuit operation. The capacitor device comprises: a first conductive layer providing a first capacitor terminal and a second conductive layer providing a second capacitor terminal and an insulating dielectric material layer therebetween, the first conductive layer, second conductive layer and insulating dielectric material layer forming a stack; a floating gate semiconductor material layer disposed within the insulating material layer and configured for storing charge carriers; a first dielectric material layer formed along a sidewall of the stack and contacting a side edge of the floating gate semiconductor material layer; a second dielectric material layer formed along an opposing sidewall of the stack and contacting an opposite side edge of the floating gate semiconductor material layer; a first conductive electrode providing a third capacitor terminal separated from the side edge of the floating gate semiconductor material layer by the first dielectric material layer, and a second conductive electrode providing a fourth capacitor terminal separated from the opposite side edge of the floating gate semiconductor material layer by the second dielectric material layer; the capacitor device associated with a weight update circuit at a crossbar array node of a neural network circuit, a capacitance of the capacitor device taken across the first and second capacitor terminals representing a weight value used in a neural network circuit operation.

In yet another aspect, there is provided a method of operating a capacitor device in a neural network circuit. The method comprises: providing a capacitor device having a first metal or heavily doped semiconductor layer defining a first capacitor terminal and second metal or heavily doped semiconductor layer defining a second capacitor terminal and an insulating material layer therebetween. The capacitor device further comprises: a floating gate semiconductor material layer disposed within the insulating material layer and configured for storing charge carriers; a first low work function metal electrode defining a third capacitor terminal separated from a first side edge of the floating gate semiconductor material layer by a first dielectric material layer, and a second high work function metal electrode defining a fourth capacitor terminal separated from a second opposing side edge of the floating gate semiconductor material layer by a second dielectric material layer; the capacitor device associated with a weight update circuit at a crossbar array node of a neural network circuit, a capacitance of the capacitor device representing a weight value used in a neural network circuit operation; and programming the weight value of the weight update circuit for the neural network circuit operation by modifying a capacitance of the capacitor device associated with the weight update circuit using both the third and fourth capacitor terminals.

Further features, as well as the structure and operation of various embodiments, are described in detail below with reference to the accompanying drawings

### BRIEF DESCRIPTION OF THE DRAWINGS

FIG. 1 shows a portion of a crossbar matrix array of a neural network hardware circuit comprising a plurality of voltage lines (rows) and current lines (columns) and a respective capacitor based complementary metal-oxide-semiconductor (CMOS) CPU device having a capacitor for storing a weight representing a synapse at each node according to one embodiment of the present disclosure;

FIG. 2 depicts a more detailed CPU based array architecture including a CPU crossbar unit operating in a first phase to charge its capacitor, e.g., for a vector-matrix deep neural network operation, at a crossbar node;

FIG. 3 depicts a second phase of a vector-matrix operation, using the cross-bar CPU-based array of FIG. 2, where the capacitors are discharged and the charge integrated using a respective charge integration unit (integrator) at an output of each respective to BL along each respective column;

FIG. 4 shows a portion of a crossbar matrix array including formed on each crossbar array node capacitor device having two additional terminals where the output product can be performed on the capacitive device array according to an embodiment of the present disclosure;

FIG. 5 depicts a cross-sectional view of the capacitor device in accordance with the CPU-based crossbar array embodiment of FIG. 4;

FIG. 6 depicts an alternate embodiment of the capacitor device of FIG. 5.

FIGS. 7A-7B depict the operations conducted to update a weight value on the crossbar node capacitor device according to the embodiment of capacitor device depicted in FIG. 5; and

FIG. 8 depicts a plot of capacitance (ordinate) versus sensed voltage values (abscissa) taken across capacitor device terminal (1) and terminal (2) and the trapping/de-trapping of charge carriers to/away from the floating gate layer according to an outer product neural network circuit operation.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. In addition, features described herein can be used in combination with other described features in each of the various possible combinations and permutations. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Unless otherwise specifically defined herein, all terms are to be given their broadest possible interpretation including meanings implied from the specification as well as meanings understood by those skilled in the art and/or as defined in dictionaries, treatises, etc. It should also be noted that, as used in the specification and the appended claims, the singular forms “a”, “an” and “the” include plural referents unless otherwise specified, and that the terms “includes”, “comprises”, and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath”, “directly under”, or “in contact with” another element, there are no intervening elements present.

Embodiments herein provide a hardware-based deep neural network (DNN) system including a number of layers containing “synaptic” weights, with each layer visualized as a 2-D arrays, i.e., a matrix, in which there is encoded weights in the matrix elements at the cross points of the arrays. The layers are connected through an activation function to convert the output from a previous layer to the input for the next layer (activation). There are two operation modes: a training mode where a deep neural network model is built and the weights are adjusted and optimized based on existing data and known results; and an inference mode, where this model (with fixed weights) is used to predict unknown results (e.g., classifying unknown objects) using available data.

During a neural network model training process there is typically performed three phases: In a first forward path phase, an input vector is fed into the DNN where it moves from layer to layer, undergoing a chain of matrix-vector multiplications (MVMs) and activations, until they reach the end of the network. For training, the intermediate input vectors for each layer are stored. The output vector of the final layer is compared with an expected value (based on the known input data) to calculate an error vector.

In a second backward-path phase, the calculated error vector or loss is used for a backpropagation algorithm and a chain rule of calculus is used to compute a gradient for each weight (and bias) of the network.

Then, in a parameter update phase: each weight and bias is updated by an amount proportional to its gradient. That is, in an update phase, during training only, the stored values of the input vector and the error vector from the forward and backward passes corresponding to each layer are recalled and used to update the weights at these layers according to a machine learning algorithm.

To accelerate the training of a DNN, a hardware-based deep neural network (DNN) analog accelerator includes a crossbar array to implement the forward, backward, and updates phases, e.g., in a method such as a stochastic gradient descent, that is implemented to find optimal configuration of parameters for the machine learning algorithm.

According to an aspect of the invention, there is provided a capacitor device. The capacitor device comprises: a first conductive layer providing a first capacitor terminal and a second conductive layer providing a second capacitor terminal and an insulating dielectric material layer therebetween, the first conductive layer, second conductive layer and insulating dielectric material layer forming a stack; a floating gate semiconductor material layer disposed within the insulating material layer and configured for storing charge carriers; a first dielectric material layer formed along a sidewall of the stack and contacting a side edge of the floating gate semiconductor material layer; a second dielectric material layer formed along an opposing sidewall of the stack and contacting an opposite side edge of the floating gate semiconductor material layer; a first conductive electrode providing a third capacitor terminal separated from the side edge of the floating gate semiconductor material layer by the first dielectric material layer, and a second conductive electrode providing a fourth capacitor terminal separated from the opposite side edge of the floating gate semiconductor material layer by the second dielectric material layer; the capacitor device associated with a weight update circuit at a crossbar array node of a neural network circuit, a capacitance of the capacitor device taken across the first and second capacitor terminals representing a weight value used in a neural network circuit operation.

The third capacitor terminal and the fourth capacitor terminal are adapted to receive signals for updating an amount of charge carriers stored at the floating gate semiconductor material layer to modify a capacitance of the capacitor device. That is, use of the third and fourth terminals enables a trapping/de-trapping of charge carriers in/from the floating gate layer to expediently decrease/increase the capacitance of the capacitor device at a given sensing voltage across terminals (1) and (2).

Moreover, the additional third and fourth terminals of the capacitor device of a CPU facilitate an analog weight update operation for an outer-product computation that is part of a deep neural network training algorithm. Each capacitor of the CPU receives at the two additional terminals either voltage or current pulses along a respective conductor connecting each respective additional terminal that shifts the capacitance of the capacitor device which significantly widens the dynamic range of capacitance tuning and improves the signal to noise ratio of the CPU-based weight storage array.

Advantageously, use of the additional third and fourth terminals of the capacitor device of a CPU provides a more expedient way to perform a gradient update fully using coincidences of voltage (stochastic) pulse trains to compute the outer product, e.g., during a parameter update phase when training the CPU-based hardware DNN.

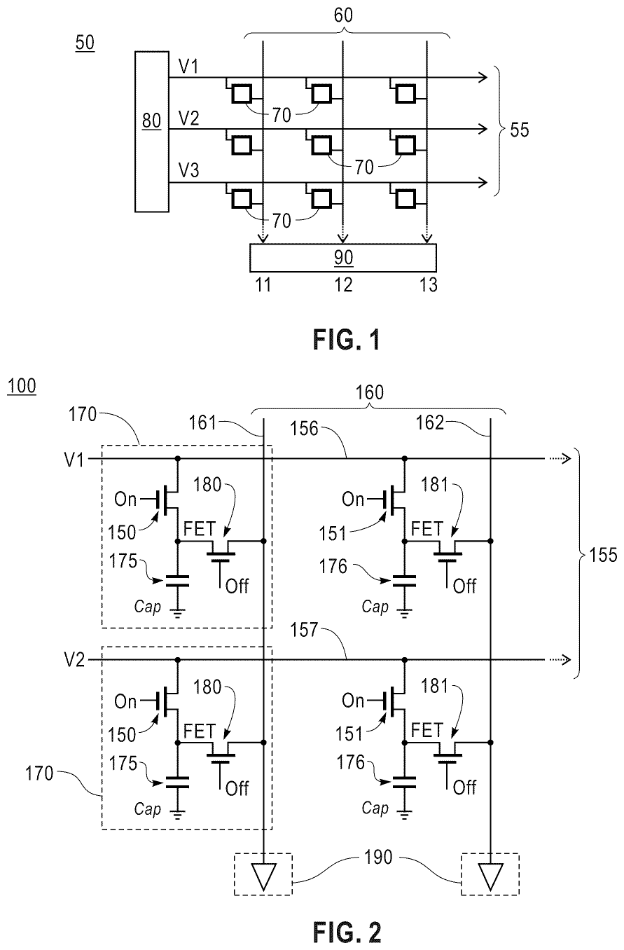

FIG. 1 shows a portion of a hardware implementation of crossbar matrix array 50 of a DNN neural network circuit. In view of FIG. 1, the example crossbar matrix array (crosspoint or crossbar array) 50 includes a plurality of voltage lines, e.g., V1, V2. V3 along rows 55 and current lines, e.g., I1, I2, I3 along columns 60 and a two terminal complementary metal-oxide-semiconductor (CMOS)-based capacitive processing unit (CPU) 70 at a crossbar “node”, i.e., at an intersection of each row line with each column line of the array 50. Each CPU 70 at a crossbar node is a two terminal, capacitive-based analog weight update circuit and includes a memory element in the form of a capacitor to store a synaptic (matrix) weight value, i.e., a variable charge stored on the update weight capacitor at the crossbar node according to one embodiment of the present invention. During a data readout (forward or backward), a voltage is applied on each column (or row) and current is collected on each row (or column).

The cross-bar matrix array configuration 50 is provided as tiles in chips to perform matrix-vector-multiplication (MVM) based operations or vector-matrix multiplication (VMM) operations. For analog processing, signal pre-processing circuitry including digital-to-analog conversion processing 80 can be provided at voltage line inputs 55 to the array 50 and other signal post-processing circuitry including analog-to-digital conversion processing 90 can be provided at current line outputs 60 of the array 50.

FIG. 2 depicts a more detailed CPU-based array architecture 100 including CPU crossbar units 170 operating in a first phase to charge its capacitor, e.g., for a vector-matrix deep neural network operation, at crossbar nodes. As shown in FIG. 2, array 100 voltage lines 155 also referred to a wordlines (WL), intersect with respective column lines 160 also referred to a bitlines (BL) with a crossbar node at each respective intersection. As shown in FIG. 2, at each crossbar node is connected a respective CPU crossbar unit 170 including a first transistor, e.g., a charging FET 150, connecting a respective voltage line, e.g., WL voltage line 156, to a first terminal of a capacitor device 175, and further includes a second transistor, e.g., a discharging or readout FET 180 connecting a column line, e.g., BL 161 with the first terminal of the capacitor device 175. The second terminal of the capacitor device 175 is connected to a ground voltage.

As shown in FIG. 2, during a matrix array charge operation, the WL voltages V1, V2, etc. at respective WLs 156, 157, etc. can represent values of a vector propagating through the array and used to charge the array of capacitors which can be preprogrammed to different capacitances to encode the values in the weight matrix. To charge the array of capacitors 175, in a first phase operation at each CPU crossbar unit 170 connecting a respective column, e.g., column 161, 162, etc. and a respective row, e.g., row 156,157, the following operations are conducted: the WL transistor 150 connecting to the capacitor 175 is programmed “On” (conducting) while the second readout transistor 180 is turned “Off”. This operation enables a product of the input voltage (WL) value, e.g., voltage V1 at row 156, with one weight capacitance value encoded as the charge on its connected capacitor “Cap” 175. Similarly, at the next node along the row 156 connecting second BL 162, the WL transistor 151 connecting to its respective capacitor 176 is programmed “On” (conducting) while the second BL transistor 181 is turned “Off” to enable a product of the input voltage (WL) value, e.g., voltage V1 at row 156, with one weight capacitance value encoded as the charge on the capacitor Cap 176. Simultaneously, at the successive (next) node along a column 161 connecting BL 161, the WL transistor 150 connecting to its respective capacitor 175 is programmed “On” while the second readout transistor 180 is turned “Off” to enable a product of the input voltage (WL) value, e.g., voltage V2 at row 157, with one weight capacitance value encoded as the charge on the capacitor Cap 175. Each CPU crossbar unit 170 at each respective charge storage capacitor 175, 176, etc. at each respective crossbar node along a respective row and column intersection can be processed at the same time to provide this vector-matrix operation and the sum charge on a respective encoded capacitor i is computed according to:

$${Q}_{i} = {C}_{i} \times {V}_{i}$$

where i is the intersection of a particular WL row at a BL column.

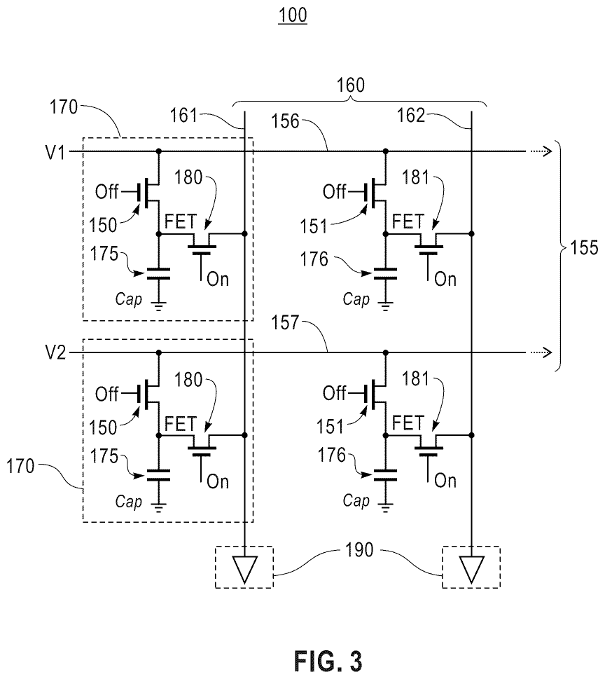

FIG. 3 depicts a second phase of a vector-matrix operation, using the crossbar CPU-based array architecture 100 of FIG. 2, where the capacitors are discharged and the charge integrated using a respective charge integration unit (integrator) 190 at an output of each respective BL column 160. That is, during a matrix array neural network multiply accumulate (MAC) operation, the charges at each capacitor 175 at each respective node along a column can represent the resulting product of the vector element propagating through the matrix array and the weight value. The stored capacitor charges are discharged such that the respective integration unit 190 at the end of a respective column can accumulate and store the charge representing the total vector-matrix multiplication result of the MAC operation at that respective BL column. To discharge the array of capacitors 175, in a second phase operation at each CPU crossbar unit 170 connecting a respective column, e.g., a BL column 161 and rows 156, 157, etc., the following operations are conducted: the WL charging transistor 150 at each row connecting to its respective capacitor 175 is programmed “Off” (non-conducting) while the second BL readout transistor 180 at each row is turned “On” (conducting). This operation enables the total charge stored at the connected capacitors 175 along BL 161 to discharge through readout transistor 180 and be received at the connected single BL column 161 for integration by its connected charge integration unit 190. Similarly, along the next BL column 162, along each row 156, 157, etc., the WL transistor 151 connecting to its respective capacitor 176 is programmed “Off” (non-conducting) while the second BL transistor 181 is turned “On” to enable the charge stored at the connected capacitor 176 to discharge through transistor 181 and received at the respective connected column line 162. Simultaneously, at the successive (next) node along column 162, the WL transistor 151 connecting to its respective capacitor 176 is programmed “Off” while the second BL transistor 181 is turned “On” to enable the total charge stored at the connected capacitors 176 along BL 162 to discharge along a single BL column 161 to be integrated by its connected charge integration unit 190 at column 162.

Each respective charge storage capacitor 175, 176, etc. at each respective CPU crossbar unit 170 of a respective crossbar node along a respective row and column intersection can be processed at the same time to provide this summed capacitor charges along a respective bitline column 161, 162, etc. of array 100. For example, along a single bitline, e.g., BL 161, the total capacitive discharge Q_{T} at integrator 190 is computed according to:

$${Q}_{T} = \sum {Q}_{i}$$

where i is the intersection of a particular WL row along that single BL column. According to neural network training algorithms, the data readout (forward or backward) is a voltage corresponding to the total charge on the capacitance of integrator 190 along the column/row.

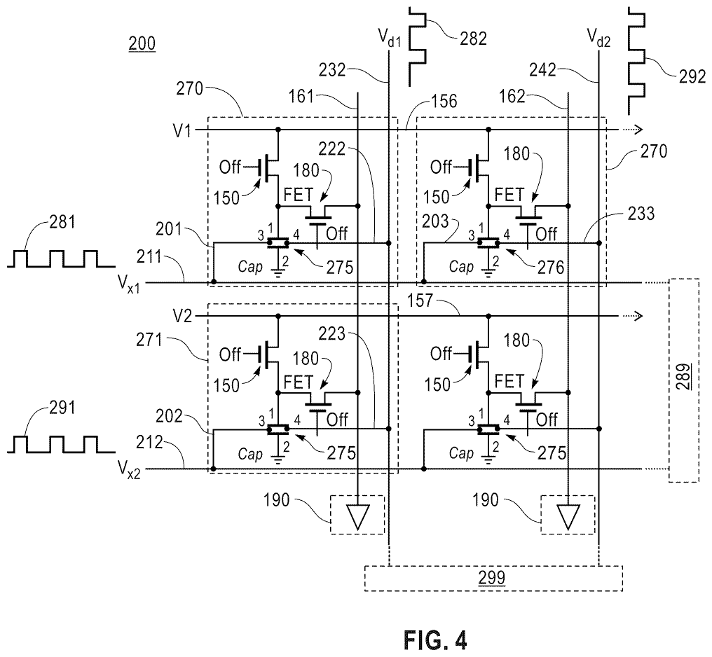

Referring now to FIG. 4, there is implemented a more expedient way to perform a gradient update fully using coincidences of voltage (stochastic) pulse trains to compute the outer product, e.g., during the parameter update phase when training the CPU-based hardware DNN. In this aspect, FIG. 4 shows a portion of a CPU-based crossbar matrix array 200 including formed on each crossbar array node a capacitor device 275 having two additional terminals where the output product can be performed on the capacitive device array according to an embodiment of the present disclosure. By sending voltage or current pulses, the capacitance of each capacitor device 275 at a crossbar array node is updated, e.g., shifted (incremented or decremented), proportional to the number of pulse coincidences. In view of FIG. 4, at a first crossbar array node 270 intersecting the first WL conductor 156 and BL conductor 161, a capacitor device 275 includes a first contact/terminal (1) connecting the wordline 156, through the FET switching device 150 and a second contact/terminal (2) connecting to a ground or neutral potential. The first (1) and second (2) contacts/terminals are used for the matrix-vector operations as described with respect to FIGS. 2 and 3. In accordance with an embodiment herein, the capacitor device 275 includes a third contact/terminal (3) and a connecting conductive structure 201 which connects the third contact/terminal (3) of capacitor 275 to a further conductor line 211 that is connected to a pulse signal generator 289. The third contact/terminal (3) of capacitor 275 is configured to receive from pulse signal generator 289 a voltage Vₓ₁ (e.g., a pulse train 281) for updating a capacitance charge at the capacitor device 275. Further, the capacitor device 275 includes a fourth contact/terminal (4) and a connecting conductive structure 222 which connects the fourth contact/terminal (4) of capacitor 275 to a further voltage line 232 that is also connected to a pulse signal generator 299. The fourth contact/terminal (4) is configured to receive from pulse signal generator 299 a further voltage V_{d1} (e.g., a pulse train 282) for updating (shifting) the capacitance charge at the capacitor device 275 accordance to the model parameter updating operation of the neural network training algorithm. The receipt of voltages Vₓ₁ and V_{d1} at capacitor 275 at a crossbar node 270 operate in conjunction to update the capacitance of the capacitor device. The third (3) and fourth (4) contacts/terminals are used for the outer-product update operations of the neural network training algorithm. That is, in a method of operation, an update phase of the neural network training algorithm computes the outer product between a backpropagated error vector “d” and an activation vector “λ”, which then needs to be added to the weight matrix. In an illustrative, non-limiting embodiment, to compute the outer product between the backpropagated error vector and the activation vector, each side of the crossbar array receives stochastic pulse trains where the probability of having a pulse is proportional to the activation vector “x” or the error vector “d”. In an embodiment, since the pulses are drawn stochastically independent, the probability of having a coincidence is given by the product of both probabilities. So, when the coincidences are causing the incremental capacitive change, the weight gradient updated is in this manner is performed in constant time for the full analog array in parallel. The change in capacitance of capacitor devices 275, 276 modulates the total charges integrated at integrator 190 when performing a next cycle of forward and backward neural network circuit operations.

The capacitor device 275, 276 having the structure depicted in FIG. 4 is provided at a CPU at each crossbar node of the matrix array 200. For example, in accordance with an embodiment depicted in FIG. 4, at the crossbar array node 271 intersecting the next WL row 157 and the same matrix array column BL 161, the capacitor device 275 includes a third contact/terminal (3) and a connecting conductive structure 202 which connects the third contact/terminal (3) of capacitor 275 to a further conductor line 212 that is formed to receive a voltage Vₓ₂ (e.g., a pulse train 291) for updating a capacitance charge at the capacitor device 275 of that array node. Further, the capacitor device 275 includes a fourth contact/terminal (4) and a connecting conductive structure 223 which connects the fourth contact/terminal (4) of capacitor 275 to the further conductor line 232 that is formed to receive the voltage V_{d1} (e.g., a further pulse train 282) for updating a capacitance charge at the capacitor device 275 accordance to the model parameter updating operation of the neural network training algorithm. The receipt of voltages Vₓ₂ and V_{d1} at capacitor 275 operate in conjunction to update the capacitance of the capacitor device at a crossbar node 271 in accordance with the outer-product update operations of the neural network training algorithm.

In accordance with the embodiments herein, the capacitor structure 275 including two additional contact/terminals (3), (4) is provided at each crossbar node of the matrix array 200. Thus, at the crossbar array node intersecting the WL row 156 and the next matrix array column BL 162, besides the contact/terminals (1) and (2) operable for matrix-vector operations, the capacitor device 276 includes a third contact/terminal (3) and a connecting conductive structure 203 which connects the third contact/terminal (3) of capacitor 276 to the further voltage line 211 that is formed to receive the voltage Vₓᵢ (e.g., a pulse train 281) for updating a capacitance charge at the capacitor device 276 of that node. The capacitor device 276 also includes a fourth contact/terminal (4) and a connecting conductive structure 233 which connects the fourth contact/terminal (4) of capacitor 276 to a further voltage line 242 that is formed to receive a further voltage V_{d2} (e.g., a pulse train 292) for updating a capacitance charge at the capacitor device 276. The receipt of voltages Vₓ₁ and V_{d2} at capacitor 276 operate in conjunction to update the capacitance of the capacitor device at that crossbar node in accordance with the outer-product update operations of the neural network training algorithm.

In accordance with the embodiments herein, the contacts/terminals (3) of each capacitor device of each CPU-based crossbar array node along a WL row, e.g., rows 156, 157 are common for the whole row and connect to a corresponding respective row, i.e., row conductors Vₓ₁, Vₓ₂, etc. Similarly, the contacts/terminal (4) of each capacitor device of each crossbar array node along a BL column, e.g., columns 161, 162 are common for the whole column and connect to a corresponding respective column, e.g., column conductors V_{d1}, V_{d2}, etc. . . . The pulse signals represented by Vₓᵢ, and V_{dj} are used to update the capacitance value for device at crossbar node location i, j. The updating of the capacitor in the CPU-based crossbar array can be according to known schemes such as, but not limited to: stochastic pulsing, deterministic pulsing, current control update for CMOS_RPU, etc. which all can be leveraged for capacitive arrays. In this manner, the whole array of capacitance values can be updated proportional to xᵢ*dⱼ.

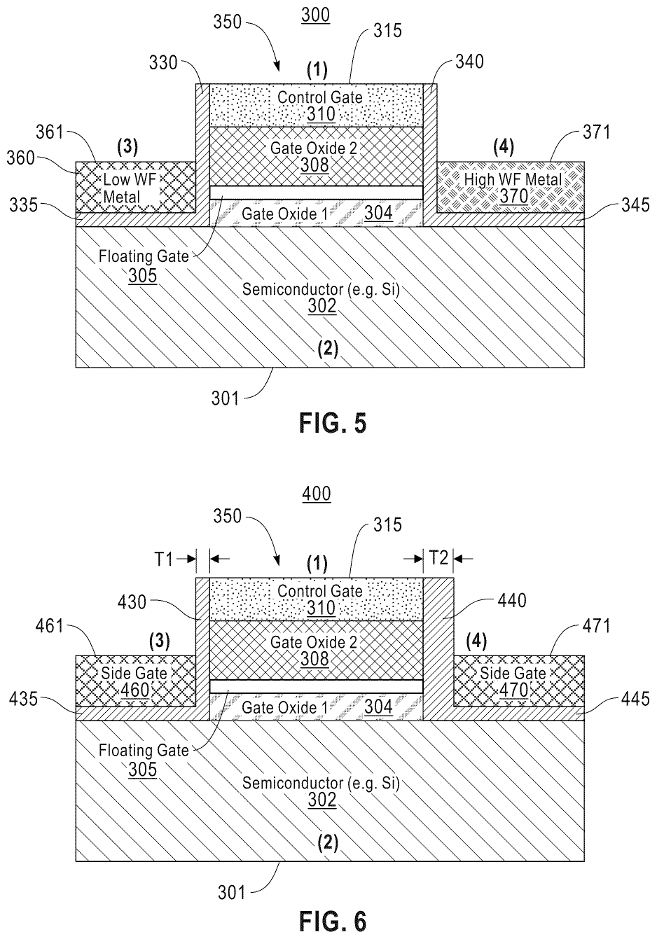

FIG. 5 depicts a cross-sectional view of the capacitor device 300 in accordance with the CPU-based crossbar array of FIG. 4. As shown, the capacitor 300 includes a stacked structure including a bottom semiconductor substrate structure 302 of a semiconductor material (or a stack of semiconductor materials) such as, for example, Si, Ge, SiGe, etc. forming and/or providing a second capacitor contact or terminal (2) 301 and upon which is formed a stack including a first gate oxide layer 304 (e.g., an oxide such as SiO₂ although other dielectric materials such as silicon nitride, silicon oxynitride, or a combination thereof, can be used) a floating gate layer 305 including a thin heavily doped layer of polysilicon formed on top of first gate oxide layer 304, a second top gate oxide layer 308 on top of the floating gate 305, and a top control gate layer 310 including heavily doped polysilicon material (e.g., a polysilicon material layer having n+ dopant) forming and/or providing a top capacitor contact or terminal (1) 315. In embodiments herein, a heavily doped material is a semiconductor material having a concentration of dopants greater than 1×10¹⁹/cm³. In a non-limiting implementation, the capacitor 300 is formed to have a default capacitance of 150 fF (femtoFarads) but could range anywhere from between 10 fF to 10 pF. The capacitor structure is formed by conventional semiconductor manufacturing techniques including successively depositing on a substrate 302 a stack including gate oxide layer 304 (e.g., 2 nm-5 nm thick), floating gate layer 305 (e.g., 2 nm-5 nm thick), second gate oxide layer 308 (e.g., 2 nm-5 nm thick), and control gate layer 310 (e.g., 30 nm-100 nm thick), and the patterning of a photoresist, developing and etching steps to form the capacitor stack 350. The stack 350 consisting of the control gate layer 310, second gate oxide layer 308, floating gate layer 305, and gate oxide layer 304 is of a width that is less than the width of the semiconductor substrate 302. Subsequently, there is deposited an oxide or like tunneling oxide dielectric material, e.g., a high-k dielectric material, along sidewalls of the stack 350 to form thin tunneling oxide material layers 330, 340. The thickness of tunneling oxide material sidewall layers 330, 340 can range between 1 nm and 5 nm in thickness. The high-k dielectric material sidewall layer 330 on one side of stack 350 is deposited to form a further horizontally disposed thin high-k dielectric material layer 335 on a top surface of the semiconductor substrate 302 and likewise, high-k dielectric material sidewall layer 340 deposited on the other side of stack 350 extends to form a further horizontally disposed thin high-k dielectric material layer 345 on the top surface of the semiconductor substrate 302 on the other side of the stack. The formed horizontally disposed thin high-k dielectric material layers 335, 345 can be of the same material and thickness.

When referring to dielectric material layers 330, 340 the term “high k” denotes any transition metal oxide material such as HfOₓ, ZrOₓ, TiOₓ, AlOₓ, TaOₓ and mixtures and silicates thereof, etc., and can be deposited by atomic layer deposition (ALD) processes or other suitable processes or any suitable combination of multiple processes, including but not limited to, thermal oxidation, chemical oxidation, thermal nitridation, plasma oxidation, plasma nitridation, atomic layer deposition (ALD), chemical vapor deposition (CVD), physical vapor deposition (PVD), molecular beam deposition (MBD), pulsed laser deposition (PLD), liquid source misted chemical deposition (LSMCD), and other like deposition processes. etc. For purposes of illustration, the high-k dielectric material layers 330, 340 can consist of a tunneling oxide material, e.g., HfO₂.

In a first embodiment, further formed on capacitor structure on top the thin high-k dielectric material 335 on a top surface of the semiconductor substrate 302 and abutting the sidewall dielectric material layer 330 is a low work-function (WF) metal side electrode 360. This low WF metal electrode 360 connects to or provides the third terminal 361 (contact/terminal (3)) of the capacitor. In this embodiment, the low work function metal side electrode 360 is of a work function material characterized, in a non limiting embodiment, as <4.6 eV. Such a low WF metal of electrode 360 can be a material such as Al, Al-containing alloy, or n+ polysilicon and can range from between 5 and 50 nm in thickness. Further formed on capacitor structure on top the thin high-k dielectric material 345 on a top surface of the semiconductor substrate 302 and abutting the sidewall dielectric material layer 340 is a high WF metal side electrode 370. This high WF metal layer 370 connects to or provides the fourth terminal 371 (contact/terminal (4)) of the capacitor. In this embodiment, the side high work function metal electrode 370 is of a work function material characterized, in a non limiting embodiment, as >4.6 eV. Such a high WF metal can be a material such as TiN, p+ polysilicon) and can range from between 5 and 50 nm in thickness. In non-limiting embodiments, the n+ and p+ dopant concentrations can be about 3×10²¹ cm³ although other dopant concentrations can be used. Other high WF metals for side electrode 370 can include but are not limited to: tantalum nitride (TaN), tungsten (W) or tungsten nitride (WN) or other materials including, but not limited to: tantalum carbide (TaC), titanium carbide (TiC), and titanium aluminum carbide (TiAlC). In embodiments, the forming of metal side electrodes 360, 370 results from deposition techniques such as CVD, PECVD, atomic layer deposition (ALD), sputtering or plating.

In the embodiment of FIG. 5, the first contact/terminal (1) 315 is connected to the control gate layer 310 and the second contact/terminal (2) 301 is connected to the semiconductor substrate 302. Terminal (3) 361 and terminal (4) 371 are defined as or connected to the respective side electrodes 360, 370. Asymmetric metals for contact/terminal (3) 361 and contact/terminal (4) 371 are required for co-incidental pulses-based programming for outer product computation of the neural network training algorithm.

FIG. 6 depicts an alternate embodiment of the capacitor device 300 of FIG. 5. In particular, FIG. 6 depicts a cross-sectional view of an alternative crossbar array node capacitor 400 that includes the bottom substrate structure such as a Si layer 302 forming the second capacitor contact or terminal (2) 301 upon which is formed a stack 350 including the first gate oxide layer 304 (e.g., an oxide such as SiO₂), the floating gate layer 305 including a thin heavily doped layer of polysilicon formed on top of first gate oxide layer 304, the second top gate oxide layer 308 on top of the floating gate 305, and the top control gate layer 310 including heavily doped polysilicon material (e.g., a polysilicon material layer having n+ dopant) forming a top capacitor contact or terminal (1) 315. The capacitor 400 including stack 350 (stack) formed on top of the semiconductor substrate 302 is of a width that is less than the width of the semiconductor substrate 302 and includes a first formed thin sidewall dielectric material layer 430 of a high-k dielectric material of a first thickness “T1” (e.g., 1.0-3.0 nm) on one side of stack 350 and includes a second formed sidewall dielectric material layer 440 of a high-k dielectric material that is of a second thickness “T2” greater than the thickness T1 of the first sidewall layer 430 (i.e., T1<T2). A second thickness of T2 can range from 3.0 nm-5.0 nm. The high-k dielectric material sidewall layer 430 on one side of stack 350 extends to form a further horizontally disposed high-k dielectric material layer 435 of like thickness on a top surface of the semiconductor substrate 302 and likewise high-k dielectric material sidewall layer 440 on the other side of stack 350 extends to form a further horizontally disposed high-k dielectric material layer 445 on the top surface of the semiconductor substrate 302 on the other side of stack 350. The thicknesses of the horizontally disposed high-k dielectric material layers 440, 445 can be the same.

Further to the alternate embodiment of the crossbar array node capacitor 400 depicted in FIG. 6, formed on capacitor structure on top the thin high-k dielectric material 435 on a top surface of the semiconductor substrate 302 and abutting the sidewall dielectric material layer 430 is a metal electrode 460. This metal electrode 460 connects to or provides a third contact/terminal 461 (contact/terminal (3)) of FIG. 4. In this embodiment, the side metal electrode 460 can be a low WF metal such as Al, Al-containing alloy, or an n+ polysilicon material. Further, formed on capacitor structure 400 on top the thin high-k dielectric material 445 on a top surface of the semiconductor substrate 302 and abutting the sidewall dielectric material layer 440 is a metal electrode 470 which can be the same low WF metal, e.g., Al, Al-containing alloy, or an n+ polysilicon material, as sidewall metal electrode 460. This metal electrode 470 connects to or provides the fourth terminal 471 (contact/terminal (4)) of FIG. 4.

While embodiments herein illustrate use of n-type dopants for the work function metals side electrodes and floating gate layer, it is understood that other embodiments contemplate use of p-type dopants for the work function metals side electrodes and floating gate layer. The term “p-type” refers to the addition of impurities to an intrinsic semiconductor that creates deficiencies of valence electrons. Examples of p-type dopants, i.e., impurities, include, but are not limited to, boron, aluminum, gallium and indium. “N-type” refers to the addition of impurities that contributes free electrons to an intrinsic semiconductor. Examples of n-type dopants, i.e., impurities, include, but are not limited to, antimony, arsenic and phosphorous.

In the capacitor 400 of the embodiment of FIG. 6, the first contact/terminal (1) 315 is connected to the control gate layer 310 and the second contact/terminal (2) 301 is connected to the semiconductor substrate 302. Terminal (3) 461 and terminal (4) 471 are defined as or connected to the respective side metal electrodes 460, 470. Asymmetric metals for contact/terminal (3) 361 and contact/terminal (4) 371 are required for co-incidental pulses-based programming for outer product computation. Asymmetric tunneling oxide thicknesses T1 and T2 on respective stack sidewalls are required for co-incidental pulses-based programming for the outer product computation. Co-incidental pulses-based programming can not work for a symmetric device, e.g., a capacitor device of FIGS. 5, 6 that include same side metal electrodes of same WF material/thickness and that have identical tunneling oxide sidewall thicknesses as such a structure would not permit a net change in the amount of trapped electrons in the floating gate due to symmetric injection and ejection at both sidewalls.

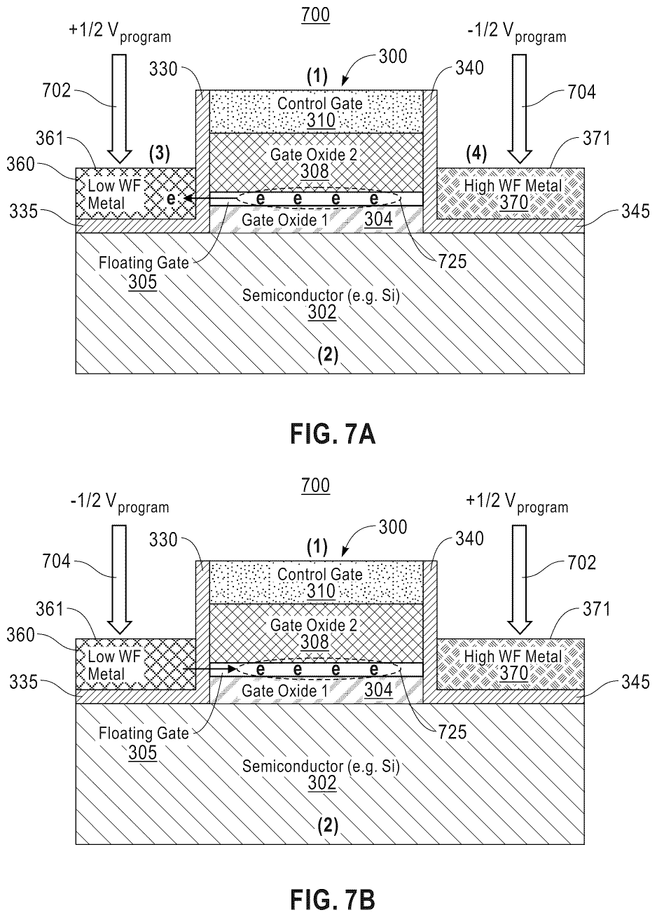

FIGS. 7A-7B depict the operations 700 to update a weight value on the crossbar node capacitor device 300 according to the embodiment of capacitor device 300 depicted in FIG. 5. As a weight value is stored as a charge on the capacitor device at a crossbar array node, the update operation involves modifying an amount of the charges stored at the floating gate layer 305 via application of voltage pulses to the metal electrode 360 (terminal (3)) and metal electrode 370 (terminal (4)) of capacitor 300 of FIGS. 7A-7B. The modification of the amount of charge stored at the floating gate layer 305 changes the capacitance of the capacitor device and consequently a sensed voltage when performing subsequent forward/backward propagation operations during neural network model training.

As shown in FIGS. 7A-7B, to perform the parameter updates for a neural network training algorithm, a fully programmed voltage (V_{program}) is applied via coincidence of two half voltage pulses 702, 704 to the respective metal electrodes 360, 370. In particular, +½ V_{program} pulses are applied to the electrode 360 (terminal (3)) and the other half −½ V_{program} pulses are applied to the electrode 370 (terminal (4)). As shown in FIG. 7A, by application of these half voltage pulses 702, 704 (in the polarity as shown) to respective side metal electrodes 360, 370, electrons 725 are tunneled from the floating gate layer 305 to the low work function metal side electrode 360 proportional to the number of pulse coincidences. In this modification, a large enough voltage is applied across the sidewall tunneling oxide layer 330 such that the charge carriers (e.g., electrons 725) are removed (de-trapped) from the floating gate layer 305 using electron tunneling. This removal of charges (e.g., electrons) from the floating gate layer 305 changes the voltage at the floating gate layer 305 which can modulate the voltage sensed when performing a next MVM operation using terminals (1) and (2) of the capacitor at that node.

As shown in FIG. 7B, by changing the polarity and applying the half voltage pulses 704, 702 (at the changed polarity) to the respective side metal electrodes 360, 370, electrons 725 are tunneled from the low work function metal side electrode 360 to the floating gate layer 305 proportional to the number of pulse coincidences. In this modification, a large enough voltage is applied across the sidewall tunneling oxide layer 330 such that the charge carriers (e.g., electrons 725) are removed from the low work function metal side electrode 360 using electron tunneling across the tunneling oxide layer 330 and are trapped at the floating gate layer 305. This removal of charges (e.g., electrons) from the low work function metal side electrode 360 to the floating gate layer 305 changes the voltage at the floating gate layer 305 which can modulate the voltage sensed when performing a next MVM operation using terminals (1) and (2).

In the embodiments of FIG. 7A-7B, the flow of charges (e.g., electrons) 725 to/from the low WF metal electrode 360 is through the thin tunneling oxide layer 330 (e.g., HfO₂) which is thin enough to allow the tunneling of electrons based on the voltage across the oxide layer 330. In the embodiment of FIGS. 7A-7B, no electron transfer across sidewall oxide layer 340 happens on electrode 370 (terminal (4)) due to a higher barrier between the defect level of tunneling oxide layer 340 and the high WF metal electrode 370.

Similar programming update results are expected when the crossbar array-node capacitor device 400 of FIG. 6 is used and subject to coincident pulses to program a weight update in like manner. That is, using the capacitor device 400 of FIG. 6 and applying the same applied voltages as in FIG. 7A, i.e., the +½ V_{program} voltage applied to electrode 460 (terminal (3)) and (an inverted bias voltage)−½ V_{program} voltage applied to electrode 470 (terminal (4)), there still would be no electron transfer across sidewall oxide layer 440 on electrode 470 (terminal (4)) due to the increased thickness “T2” of the sidewall tunneling oxide layer 440 which prevents tunneling of charges (e.g., electrons) across the tunneling oxide layer 440 to/from the low WF metal electrode 470.

In an embodiment, the application of +½ V_{program} and −½ V_{program} coincident programming pulsed voltages to respective side electrodes 360, 370 is shown for illustrative purposes. The embodiments herein are not limited to applying this ratio (+½, −½) of V_{program} pulses but rather a different ratio of the programming voltages (V_{program}) can be applied to respective metal electrodes 360, 370, e.g., +¼ V_{program} and −¾ V_{program} or −¼ V_{program} and +¾ V_{program}.

Referring back to FIG. 4, with respect to a capacitance weight update phase at a first crossbar array node 270, both FET transistor devices 150, 180 are turned off (non-conducting) and the +½ V_{program} voltage applied to terminal (3) of capacitor 275 is conducted via the further conductor line 211 that is connected to a pulse signal generator 289 that provides a programmed voltage Vₓ₁ (e.g., a voltage pulse train 281) and simultaneously, the −½ V_{program} voltage applied to terminal (4) is conducted via the further conductor line 232 that is connected to a pulse signal generator 299 configured to provide a programmed voltage V_{d1} (a voltage pulse train 282). In embodiments, the pulses can have amplitudes of about 1.5V however, can range from between 1.0 and 3.0 volts and can be a pulse duration ranging from about 5 ns to 100 ns (e.g., 10 ns). In embodiments, the programmed voltage V_{program} is dependent upon the thickness of the tunneling oxide layers and capacitor device physics to ensure trapping of electrons and the pulse frequency is dependent upon input values. Each weight update operation of the capacitor devices at each crossbar node of the matrix array is similarly programmed. For example, with respect to a crossbar array node 271 along BL column 161, both transistor devices 150, 180 are turned off and the +½ V_{program} voltage applied to terminal (3) is via the further conductor line 212 that is connected to a pulse signal generator 289 configured to provide a voltage Vₓ₂ (e.g., a voltage pulse train 291) and simultaneously, the −½ V_{program} voltage applied to terminal (4) is via the further conductor line 232 that is connected to the pulse signal generator 299 and configured to provide a voltage V_{d1} (a voltage pulse train 282). Similarly, with respect to a crossbar array node 270 along BL column 162, both transistor devices 150, 180 are turned off and the +½ V_{program} voltage applied to terminal (3) of capacitor 276 is via the further conductor line 211 that is connected to a pulse signal generator 289 and configured to provide a voltage Vₓ₁ (e.g., voltage pulse train 281) and simultaneously, the −½ V_{program} voltage applied to terminal (4) is via the further conductor line 242 that is connected to the pulse signal generator 299 and configured to provide a voltage V_{d2} (a voltage pulse train 292).

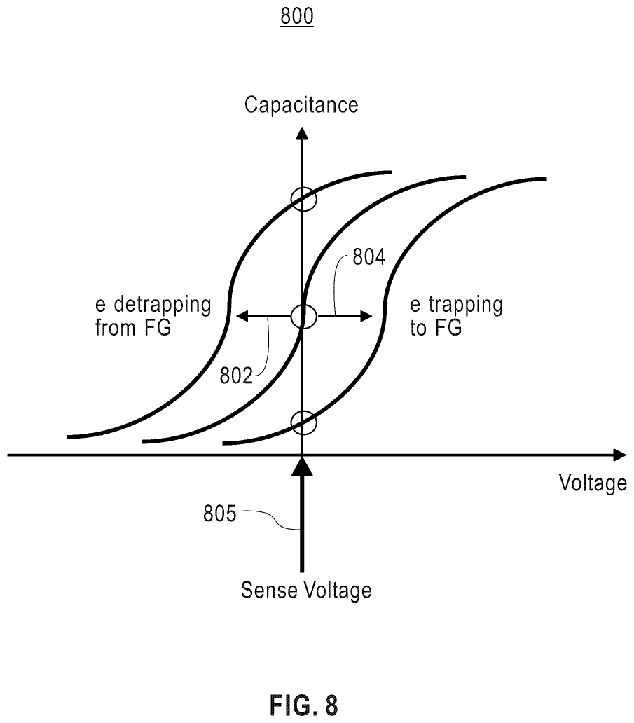

In embodiments of FIGS. 7A-7B, the programmed or updated states in the crossbar matrix array resulting from the outer-product operation to form the weight gradients for the neural network training algorithm are sensed by changes of capacitance between control gate layer 310 at terminal (1) and substrate layer 302 at terminal (2). The asymmetric capacitor device structure results in capacitance-voltage curve shifts to positive or negative depending on electron trapping or de-trapping to/from the floating gate layer 305 during the programming step. For example, in the embodiments shown in FIG. 7A-7B, to negatively shift the floating gate layer voltage (Vfb or flatband voltage) of the crossbar array node capacitor device, respective +½ V_{program} and −½ V_{program} are applied to side electrode 360 (terminal (3)) and to side electrode 370 (terminal (4)), respectively, to tunnel charge carriers (electrons) away from the floating gate layer 305 and into the metal electrode 360. As shown in FIG. 8 depicting a plot 800 of device capacitance (ordinate axis) versus sensed voltage values (abscissa) taken across capacitor device terminal (1) and terminal (2), the de-trapping of charge carriers such as electrons away from the floating gate layer reduces, i.e., shifts laterally in the negative direction 802, resulting in increase of capacitance at a given sensing voltage across terminals (1) and (2). Alternately, to positively shift the capacitance-voltage curve, −½ V_{program} and +½ V_{program} are applied to electrode 360 (terminal (3)) and to electrode 370 (terminal (4)), respectively to tunnel charges (electrons) from the metal electrode 360 to the floating gate layer 305. As shown in the plot 800 of FIG. 8, the trapping of charge carrier such as electrons in the floating gate layer adds, i.e., shifts laterally in the positive direction 804, resulting in decrease of capacitance at a given sensing voltage 805 across terminals (1) and (2).

In the case of an embodiment where the CPU at a crossbar array node includes a symmetric crossbar array node capacitor device, where the sidewall oxides are the same thickness and the side metal electrodes are the same material, e.g., both have a same WF metal (e.g., Al or doped polysilicon), application of co-incidental pulses based programming will result in no net change in the amount of trapped electrons in the floating gate to the symmetric injection and ejection at both sidewalls, i.e., no change in the position of the capacitance-voltage curve.

As known, training of a DNN is an extremely computationally intensive task that requires massive computational resources and enormous training time. Training the DNNs generally relies on the backpropagation algorithm that is intrinsically local and parallel. Various hardware approaches to accelerate DNN training that are exploiting this locality and parallelism have been explored with use of GPU, a FPGA or specially designed ASICs. Acceleration is possible by fully utilizing the locality and parallelism of an algorithm.

The CPU-based capacitive device matrix array of FIG. 4 can be used to accelerate a DNN training application including the outer-product computations of a DNN training algorithm. Generalized DNN training steps (e.g., a backpropagation algorithm) is composed of three cycles, forward, backward and weight update that are repeated many times until a convergence criterion is met. The forward and backward cycles mainly involve computing vector-matrix multiplication in forward and backward directions. This DNN training algorithm using the CPU-based 2D crossbar array 200 of capacitor devices having additional terminals such as shown in FIG. 4 can include:
1. Initializing the capacitance of each capacitor device that hold the synaptic weights randomly at a crossbar node CPU. This could be achieved by performing read-write-verify on each capacitive device;
2) Performing a forward propagation of the input signal using a Mat-Vec capability of the CPU-based capacitive array using capacitor device terminals (1) and (2). This is achieved by performing the steps illustrated in FIGS. 2 and 3. In the forward cycle, stored conductance values in the crossbar array form a matrix, whereas an input vector is transmitted as voltage pulses through each of the input rows, for example.
3. Performing a backward propagation of the error signal using transposed Mat-Vec capability of the CPU-based capacitive array using capacitor device terminals (1) and (2). This is also achieved by performing the steps illustrated in FIGS. 2 and 3. Simply the direction of the signals are transposed, i.e., in a backward cycle, when voltage pulses are supplied from columns as an input, then the vector-matrix product is computed on the transpose of a matrix. During a neural network readout operation (forward or backward propagation cycle), an input voltage vector [Vᵢ] is applied to the rows of the array which drives a current vector [Iⱼ] that is collected at the end of the columns of the array; and
4. Then, in contrast to forward and backward cycles, implementing the weight update on a 2D crossbar array of capacitive devices locally and all in parallel, independent of the array size, requires calculating a vector-vector outer product which consist of a multiplication operation and an incremental weight update to be performed locally at each cross-point. Using the signals propagated in forward and backward directions, there is performed the parallel update of the CPU-based capacitive array using terminals (3) and (4) (the outer-product capability). Signals can be generated using stochastic programming techniques, e.g., as stochastic pulses, and supplied simultaneously to the columns and rows that are connected to respective terminals (3) and (4) as shown in FIG. 4.
5. Steps 2 thru 4 are repeated until a convergence is achieved.

Employing the CPU-based capacitive crossbar array 200 such as shown in FIG. 4 as a system employing thousands of CPU elements enables the tackling of “Big Data” problems with trillions of parameters that is currently impossible to address such as, for example, natural speech recognition and translation between all world languages, real-time analytics on large streams of business and scientific data, integration, and analysis of multimodal sensory data flows from a massive number of IoT (Internet of Things) sensors.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A capacitor device comprising:
first conductive layer providing a first capacitor terminal and a second conductive layer providing a second capacitor terminal and an insulating dielectric material layer therebetween, said first conductive layer, second conductive layer and insulating dielectric material layer forming a stack;
a floating gate semiconductor material layer disposed within the insulating material layer and configured for storing charge carriers;
a first dielectric material layer formed along a sidewall of said stack and contacting a side edge of said floating gate semiconductor material layer;
a second dielectric material layer formed along an opposing sidewall of said stack and contacting an opposite side edge of said floating gate semiconductor material layer;
a first conductive electrode providing a third capacitor terminal separated from the side edge of the floating gate semiconductor material layer by the first dielectric material layer, and
a second conductive electrode providing a fourth capacitor terminal separated from the opposite side edge of the floating gate semiconductor material layer by the second dielectric material layer; said capacitor device associated with a weight update circuit at a crossbar array node of a neural network circuit, a capacitance of said capacitor device taken across said first and second capacitor terminals representing a weight value used in a neural network circuit operation.

2. The capacitor device as claimed in claim 1, wherein said first dielectric material layer formed along a sidewall of said stack comprises a first horizontal dielectric material layer portion extending on a top surface of said first semiconductor material layer on one side of said stack, and the second dielectric material layer formed on an opposing sidewall of said stack comprises a second horizontal layer portion extending on a top surface of said first semiconductor material layer on another side of said stack, wherein
the first conductive electrode is formed on said horizontal dielectric material layer portion and abutting the first dielectric material layer formed on the sidewall of said stack; and
the second conductive electrode formed on said second dielectric material layer and abutting the second dielectric material layer formed on the opposing sidewall of said stack, wherein said third capacitor terminal and said fourth capacitor terminal are adapted to receive signals for updating an amount of charge carriers stored at said floating gate semiconductor material layer to modify a capacitance of said capacitor device.

3. The capacitor device as claimed in claim 2, wherein said first conductive electrode comprises a low work function metal material, and said second conductive electrode comprises a high work function metal material.

4. The capacitor device as claimed in claim 3, wherein said first dielectric material layer and second dielectric material layer are of substantially identical thickness.

5. The capacitor device as claimed in claim 3, wherein one of said first dielectric material layer and second dielectric material layer comprises an oxide material of a thickness permitting tunneling of charge carriers therethrough for incrementing or decrementing an amount of charge carriers stored in said floating gate semiconductor material layer.

6. The capacitor device as claimed in claim 5, wherein both said first conductive electrode and second conductive electrode comprise a low work function metal material.

7. The capacitor device as claimed in claim 6, wherein said second dielectric material layer is of a thickness greater than a thickness of said first dielectric material layer.

8. The capacitor device as claimed in claim 2, wherein said capacitor device is a connected to a weight update circuit at a crossbar array node of a neural network circuit adapted to conduct neural network operations, a capacitance of said capacitor device representing a weight value used in a neural network circuit operation.

9. The capacitor device as claimed in claim 8, wherein the weight update circuit at the crossbar array node of the neural network circuit comprises:
a first conductor structure operatively connected to said third capacitor terminal and adapted to conduct a first pulsed signal from a signal generator to said third capacitor terminal; and
a second conductor structure operatively connected to said fourth capacitor terminal and adapted to conduct a second pulsed signal from the signal generator to said fourth capacitor terminal, said first pulsed signal and second pulsed signals used to update said capacitance of said capacitor device during an outer-product update neural network circuit operation.

10. A neural network circuit comprising:
a crossbar array comprising a plurality of nodes; each node comprising a capacitive processing unit (CPU) including a capacitor device configured to store a charge representing a weight value associated with a neural network circuit operation, the capacitor device comprising:
first conductive layer providing a first capacitor terminal and a second conductive layer providing a second capacitor terminal and an insulating dielectric material layer therebetween, said first conductive layer, second conductive layer and insulating dielectric material layer forming a stack;
a floating gate semiconductor material layer disposed within the insulating material layer and configured for storing charge carriers;
a first dielectric material layer formed along a sidewall of said stack and contacting a side edge of said floating gate semiconductor material layer;
a second dielectric material layer formed along an opposing sidewall of said stack and contacting an opposite side edge of said floating gate semiconductor material layer;
a first conductive electrode providing a third capacitor terminal separated from the side edge of the floating gate semiconductor material layer by the first dielectric material layer, and
a second conductive electrode providing a fourth capacitor terminal separated from the opposite side edge of the floating gate semiconductor material layer by the second dielectric material layer; said capacitor device associated with a weight update circuit at a crossbar array node of a neural network circuit, a capacitance of said capacitor device taken across said first and second capacitor terminals representing a weight value used in a neural network circuit operation.

11. The neural network circuit as claimed in claim 10, wherein said first dielectric material layer formed along a sidewall of said stack comprises a first horizontal dielectric material layer portion extending on a top surface of said first semiconductor material layer on one side of said stack, and the second dielectric material layer formed on an opposing sidewall of said stack comprises a second horizontal layer portion extending on a top surface of said first semiconductor material layer on another side of said stack, wherein
the first conductive electrode is formed on said horizontal dielectric material layer portion and abutting the first dielectric material layer formed on the sidewall of said stack, and
the second conductive electrode formed on said second dielectric material layer and abutting the second dielectric material layer formed on the opposing sidewall of said stack,
said third capacitor terminal and said fourth capacitor terminal adapted to receive signals for updating an amount of charge carriers stored at said floating gate semiconductor material layer to modify a capacitance of said capacitor device.

12. The neural network circuit as claimed in claim 11, wherein the CPU at a crossbar array node of the neural network circuit comprises:
a first Field Effect Transistor (FET) device operatively connecting a first conductor line to said first capacitor terminal and adapted to conduct a signal from a voltage source to charge said capacitor device for use in a matrix vector multiplication neural network operation; and
a second FET device operatively connecting a second conductor line to said second capacitor terminal and adapted to conduct a signal representing said charge stored at said capacitor device to a charge integrator device for use in said matrix vector multiplication neural network circuit operation.

13. The neural network circuit as claimed in claim 12, wherein the CPU comprises a weight update circuit at the crossbar array node of the neural network circuit, said weight update circuit comprising:
a third conductor line operatively connected to said third capacitor terminal and adapted to conduct a first pulsed signal from a signal generator to said third capacitor terminal; and
a fourth conductor line operatively connected to said fourth capacitor terminal and adapted to conduct a second pulsed signal from the signal generator to said fourth capacitor terminal, said first pulsed signal and second pulsed signals used to update said capacitance of said capacitor device during an outer-product update neural network circuit operation.

14. The neural network circuit as claimed in claim 11, wherein said first conductive electrode comprises a low work function metal material, and said second conductive electrode comprises a high work function metal material, said first dielectric material layer and second dielectric material layer being of substantially identical thickness.

15. The neural network circuit as claimed in claim 11, wherein one of said first dielectric material layer and second dielectric material layer comprises an oxide material of a thickness permitting tunneling of charge carriers therethrough for incrementing or decrementing an amount of charge carriers stored in said floating gate semiconductor material layer.

16. The neural network circuit as claimed in claim 11, wherein both said first conductive electrode and second conductive electrode comprise a low work function metal material, said second dielectric material layer being of a thickness greater than a thickness of said first dielectric material layer.

17. A method of operating a capacitor device in a neural network circuit, the method comprising:
providing a capacitor device having a first metal or heavily doped semiconductor layer defining a first capacitor terminal and second metal or heavily doped semiconductor layer defining a second capacitor terminal and an insulating material layer therebetween, the capacitor device further comprising:
a floating gate semiconductor material layer disposed within the insulating material layer and configured for storing charge carriers;
a first low work function metal electrode defining a third capacitor terminal separated from a first side edge of the floating gate semiconductor material layer by a first dielectric material layer, and
a second high work function metal electrode defining a fourth capacitor terminal separated from a second opposing side edge of the floating gate semiconductor material layer by a second dielectric material layer; said capacitor device associated with a weight update circuit at a crossbar array node of a neural network circuit, a capacitance of said capacitor device representing a weight value used in a neural network circuit operation; and
programming the weight value of said weight update circuit for said neural network circuit operation by modifying a capacitance of the capacitor device associated with said weight update circuit using both the third and fourth capacitor terminals.

18. The method as claimed in claim 17, wherein said modifying a capacitance of the capacitor device comprises:
simultaneously applying a first pulsed signal to said third capacitor terminal and applying a second pulsed signal to said fourth capacitor terminal to control one of: a trapping of charge carriers to or a de-trapping of charge carriers from the floating gate semiconductor material layer.

19. The method as claimed in claim 17, further comprising:
sensing a capacitance value of said capacitor device using both the first and second capacitor terminals, said sensing comprising:
applying a sensing voltage at said capacitor device and detecting a voltage across said first capacitor terminal and said second capacitor terminal; and
detecting a programmed weight update state based on a voltage sensed across the first capacitor terminal and said second capacitor terminal.

20. The method as claimed in claim 18, wherein the applied first pulsed signal and applied second pulsed signal comprise respective voltage values according to a predetermined ratio.
